(19) United States
(12) Patent Application Publication
(10) Pub. No.: US 2009/0322346 A1
(43) Pub. Date: Dec. 31, 2009

(54) MOTHERBOARD TEST SYSTEM AND TEST METHOD THEREOF

(75) Inventor: XIANG CAO, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (TW); HON HAI PRECISION INDUSTRY CO., LTD., Tu-Cheng (TW)

(21) Appl. No.: 12/211,058

(22) Filed: Sep. 15, 2008

(30) Foreign Application Priority Data
Jun. 25, 2008 (CN) 200810302311.8

(51) Int. Cl. G01R 31/3181

(52) U.S. Cl. 324/555

(57) ABSTRACT

A motherboard test system for testing a motherboard includes a number of HDDs storing different operating systems, a number of HDD connectors corresponding to the HDDs, a number of electrical switches connecting power terminals of the HDD connectors to a power supply, a microcontroller controlling which electrical switch is turned on, and a computer. The motherboard is connected to signal terminals of the HDD connectors to read and implement the operating system of a powered HDD, and sends the operating result to the computer.

### BACKGROUND

1. Field of the Invention

The disclosure relates to motherboard testing, and particularly to a motherboard test system and method.

2. Description of Related Art

Often, different operating systems are used when testing motherboards. A number of different operating systems and HDDs storing the same may be needed to test a single board.

What is needed, therefore, is a motherboard test system and method providing independent switching of a number of HDDs.

### BRIEF DESCRIPTION OF THE DRAWINGS

FIG. 1 is a block diagram of a motherboard test system in accordance with an embodiment of the disclosure, with a motherboard to be tested.

FIGS. 2 and 3 are flowcharts of a motherboard test method in accordance with an embodiment of the disclosure.

### DETAILED DESCRIPTION

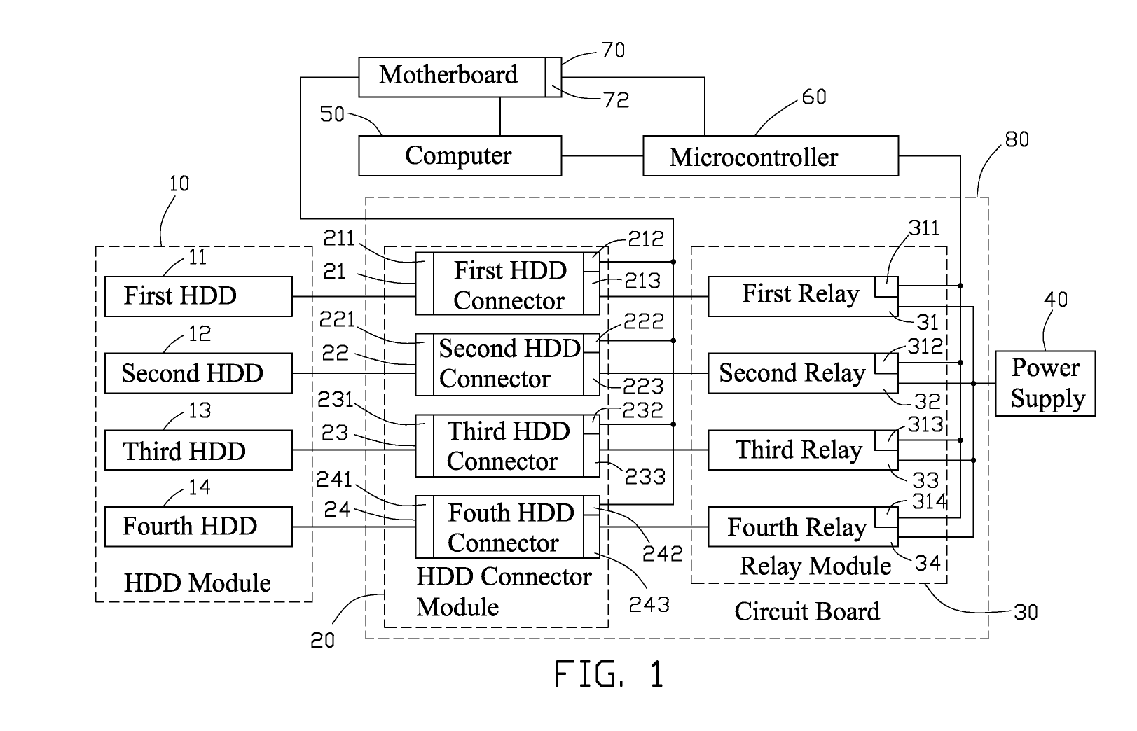

Referring to FIG. 1, a motherboard test system in accordance with an embodiment of the disclosure includes an HDD module 10, an HDD connector module 20, a relay module 30 comprising relays as electrical switches, a power supply 40, a computer 50, and a microcontroller 60.

The HDD module 10 includes first-fourth HDDs 11-14 which, here, are SATA HDDs. The HDD connector module 20 includes first-fourth HDD connectors 21-24 which, here, are serial ATA (SATA) interface HDD connectors. The first-fourth HDD connectors 21-24 each include an HDD interface 211-241, a signal terminal 212-242, and a power terminal 213-243. The relay module 30 includes first-fourth relays 31-34. The first-fourth relays 31-34 each include a control terminal 311-341. The HDD connector module 20 and the relay module 30 can be mounted on a circuit board 80.

The first-fourth HDDs 11-14 are received in the first-fourth HDD connectors 21-24 via the first-fourth HDD interfaces 211-241 respectively. The first-fourth signal terminals of the first-fourth connector 21-24 are connected to corresponding signal terminals of a motherboard 70 to communicate with the motherboard 70. The first relay 31 is connected to the first HDD connector 21 and the power supply 40. The second relay 32 is connected to the second HDD connector 22 and the power supply 40. The third relay 33 is connected to the third HDD connector 23 and power supply 40. The fourth relay 34 is connected to the fourth HDD connector 24 and the power supply 40. The microcontroller 60 is connected to the control terminals 313-343 of the first-fourth relays 31-34 to turn the first-fourth relays 31-34 on or off to switch the power supply 40 to one of the first-fourth HDDs 11-14. The microcontroller 60 is connected to an on/off pin 72 of the motherboard 70 to start and stop the motherboard 70. The computer 50 is connected to the microcontroller 60 to direct the microcontroller 60 to send commands. The computer 50 is connected to the motherboard 70 to display status information of the motherboard 30.

In other embodiments, the first-fourth HDDs 11-14 also can be other kinds of HDDs. The number of HDD connectors and relays can be varied according to test needs.

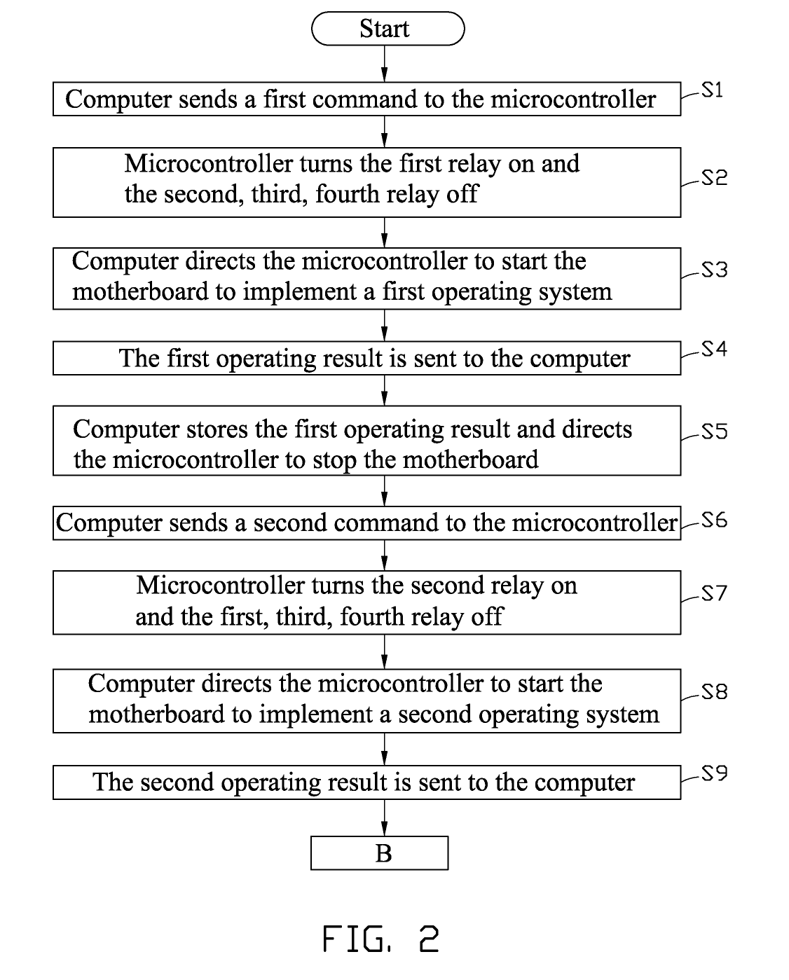

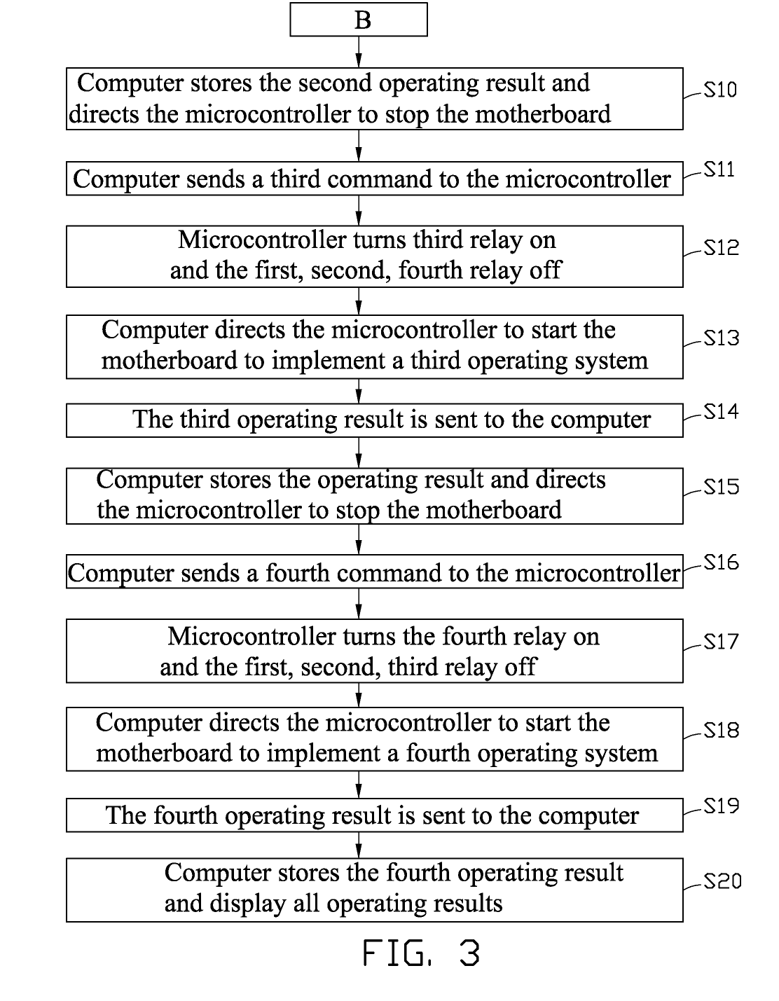

Referring to FIGS. 2 and 3, a motherboard test method utilizing the motherboard test system in accordance with an exemplary embodiment is used to test the motherboard 70. Before testing, first-fourth operating systems, reflecting the load and interference of the motherboard 70, are installed in the first-fourth HDDs 11-14 respectively. The motherboard test method includes the following steps.

In Step 1, the computer 50 sends a first command to the microcontroller 60.

In Step 2, the microcontroller 60 turns the first relay 31 on, and the second, third, and fourth relays 32-34 off according to the first command, such that the power supply 40 supplies power to only the first HDD 11 via the first relay 31.

In Step 3, the computer 50 directs the microcontroller 60 to start the motherboard 70, which in turn implements the first operating system stored in the first HDD 11.

In Step 4, upon recognition that operation of the first operating system is complete, the first operating result is sent to the computer 50.

In Step 5, the computer 50 stores the first operating result and directs the microcontroller 60 to stop the motherboard 70.

In Step 6, the computer 50 sends a second command to the microcontroller 60.

In Step 7, the microcontroller 60 turns the second relay 32 on, and the first, third, and fourth relays 31, 33, and 34 off according to the second command, such that the power supply 40 supplies power to only the second HDD 12 via the second relay 32.

In Step 8, the computer 50 directs the microcontroller 60 to start the motherboard 70, which in turn implements the second operating system stored in the second HDD 12.

In Step 9, upon recognition that operation of the second operating system is complete, the second operating result is sent to the computer 50.

In Step 10, the computer 50 stores the second operating result and directs the microcontroller 60 to stop the motherboard 70.

In Step 11, the computer 50 sends a third command to the microcontroller 60.

In Step 12, the microcontroller 60 turns the third relay 33 on, and the first, second, and fourth relays 31, 32, and 34 off according to the third command, such that power supply 40 supplies power to only the third HDD 13 via the third relay 33.

In Step 13, the computer 50 directs the microcontroller 60 to start the motherboard 70, which in turn implements the third operating system stored in the third HDD 13.

In Step 14, upon recognition that operation of the third operating system is complete, the third operating result is sent to the computer 50.

In Step 15, the computer 50 stores the third operating result and directs the microcontroller 60 to stop the motherboard 70.

In Step 16, the computer 50 sends a fourth command to the microcontroller 60;

In Step 17, the microcontroller 60 turns the fourth relay 34 on, and the first, second, and third relays 31, 32, and 33 off according to the fourth command, such that power supply 40 supplies power to only the fourth HDD 14 via the fourth relay 34.

In Step 18, the computer 50 directs the microcontroller 60 to start the motherboard 70, which in turn implements the fourth operating system stored in the fourth HDD 14.

In Step 19, upon recognition that operation of the fourth operating system is complete, the fourth operating result is sent to the computer 50.

In Step 20, the computer 50 stores the fourth operating result and displays all stored operating results.

In this embodiment, all the operating results denote load and interference characteristics of the motherboard 70.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A motherboard test system, comprising:
a first hard disk drive (HDD) and a second HDD, each storing an operating system;
a first HDD connector comprising a first HDD interface connected to the first HDD, the first HDD interface comprising a first signal terminal connected to a motherboard to be tested, and a first power terminal;
a second HDD connector comprising a second HDD interface connected to the second HDD, the second HDD interface comprising a second signal terminal connected to the motherboard, and a second power terminal;
a power supply;
a first electrical switch connecting the first power terminal and the power supply, and comprising a first control terminal;
a second electrical switch connecting the second power terminal and the power supply, and comprising a second control terminal;
a computer configured for sending commands; and
a microcontroller receiving the commands from the computer and connected to the first and second control terminals to turn the first and second electrical switches on or off according to the command, thereby directing the power supply to provide power to the first or second HDD, such that the motherboard is capable of reading and operating the operating system in the powered HDD.

2. The motherboard test system as claimed in claim 1, wherein the microcontroller is connected to an on/off pin of the motherboard to turn off the motherboard when operation of the operating system is complete.

3. The motherboard test system as claimed in claim 1, wherein the computer is connected to the motherboard to display operating results of the operating system.

4. The motherboard test system as claimed in claim 1, wherein the first and second HDD connectors and the first and second electrical switches are integrated in a circuit board.

5. The motherboard test system as claimed in claim 1, wherein the first and second HDDs are Serial ATA (SATA) interface HDDs, and the first and the second HDD connectors are SATA interface HDDs.

6. A motherboard test method applied to the motherboard test system as claimed in claim 1, comprising:
sending a first command from the computer to the microcontroller;
turning the first electrical switch on and the second electrical switch off according to the first command, such that the power supply provides power to only the first HDD via the first electrical switch;
the computer directing the microcontroller to start the motherboard to implement the operating system stored in the first HDD;
sending a first operating result from the motherboard to the computer upon recognition that operation of the first operating system is complete;
storing the first operating result and the computer directing the microcontroller to turn off the motherboard;
sending a second command from the computer to the microcontroller;
turning the second electrical switch on, and the first electrical switch off according to the second command, such that the power supply provides power to only the second HDD;
directing the microcontroller to start the motherboard to implement the operating system stored in the second HDD using the computer;
sending a second operating result from the motherboard to the computer upon recognition that operation of the second operating system is complete; and
storing the second operating result and displaying the first and second operating results using the computer.

7. The motherboard test method as claimed in claim 6, wherein the first and second electrical switches are relays.

8. The motherboard test method as claimed in claim 6, wherein the first and second HDD are Serial ATA (SATA) interface HDDs; and the first and second HDD connectors are SATA interface HDD connectors.
